(19) United States
(12) Patent Application Publication
(10) Pub. No.: US 2012/0088317 A1
(43) Pub. Date: Apr. 12, 2012

(54) PROCESSING METHOD OF SILICON SUBSTRATE AND PROCESS FOR PRODUCING LIQUID EJECTION HEAD

(75) Inventors: Keisuke Kishimoto, Yokohama-shi (JP); Shuji Koyama, Kawasaki-shi (JP); Hiroyuki Abo, Tokyo (JP); Taichi Yonemoto, Isehara-shi (JP)

(73) Assignee: CANON KABUSHIKI KAISHA, Tokyo (JP)

(21) Appl. No.: 13/226,113

(22) Filed: Sep. 6, 2011

(30) Foreign Application Priority Data
Oct. 6, 2010 (JP) 2010-226452

(51) Int. Cl. H01L 21/308

(52) U.S. Cl. 438/21; 438/694; 257/E21.231

(57) ABSTRACT

A processing method of a silicon substrate, including forming on a back surface of a silicon substrate an etching mask layer having an opening portion, measuring a thickness of the silicon substrate, irradiating the opening portion in the etching mask layer with laser from the back surface of the silicon substrate to form in the silicon substrate a modified layer with a thickness that is varied according to the measured thickness of the silicon substrate, carrying out anisotropic etching with regard to the silicon substrate having the modified layer formed therein to form in the back surface a depressed portion which does not pass through the silicon substrate and which has a bottom surface in the silicon substrate, and carrying out dry etching in the depressed portion to form a through-hole passing from the bottom surface of the depressed portion to a front surface of the silicon substrate.

### BACKGROUND OF THE INVENTION

1. Field of the Invention

The present invention relates to a processing method of a silicon substrate for forming a through-hole in the silicon substrate and to a process for producing a liquid ejection head.

2. Description of the Related Art

It is known to process a silicon substrate to form a depressed portion, a through-hole, a surface film, and the like so that the processed silicon substrate is applied to electronic device components and micro electro mechanical systems (MEMS). A silicon substrate is also used in a part of a liquid ejection head applied to an ink jet recording system or the like, and, in the production process thereof, the silicon substrate is processed as described above.

U.S. Pat. No. 6,273,557 discloses a method of forming two kinds of ink supply ports in an ink jet print head. More specifically, first, an etching stop layer is formed on a front surface of a substrate in a portion which corresponds to an opening portion. The silicon substrate has an opening portion in a back surface thereof, and an anisotropic etchant is used to etch the substrate from the opening portion in the back surface halfway through the substrate to form a depressed portion which corresponds to a first ink supply port portion. A resist is used to mask the inside of the depressed portion to open only a portion of the front surface to be opened. After that, by using anisotropic dry etching to form a through-hole passing through to the etching stop layer in the front surface portion, a second ink supply port portion is formed. In this way, the two kinds of ink supply ports are formed.

However, dispersion in the thickness of the silicon substrate may occur among sliced wafers. Therefore, when a large number of substrates are processed at a time, depending on the dispersion in the substrate thickness, the remaining amount of silicon after etching for forming the depressed portion corresponding to the first ink supply port portion may vary. As a result, dispersion in the time required for dry etching for forming the through-hole corresponding to the second ink supply port portion may be caused among substrates, thus causing an error in the opening size.

### SUMMARY OF THE INVENTION

Accordingly, an object of the present invention is to provide a processing method of a silicon substrate and a process for producing a liquid ejection head which are capable of suppressing the influence of dispersion in substrate thickness so as to form an opening in the silicon substrate with good size precision, to thereby improve production efficiency.

In order to achieve the above-mentioned object, according to the present invention, there is provided a processing method of a silicon substrate, including the steps of; (a) forming on a back surface of a silicon substrate an etching mask layer having an opening portion, (b) measuring a thickness of the silicon substrate, (c) irradiating the opening portion in the etching mask layer with laser from the back surface of the silicon substrate to form in the silicon substrate a modified layer with a thickness that is varied according to the measured thickness of the silicon substrate, (d) carrying out anisotropic etching with regard to the silicon substrate having the modified layer formed therein to form a depressed portion which does not pass through the silicon substrate and which has a bottom surface in the silicon substrate, and (e) carrying out dry etching in the depressed portion to form a through-hole passing from the bottom surface of the depressed portion to a front surface of the silicon substrate.

Further, according to the present invention, there is provided a process for producing a liquid ejection head in which a liquid supply port is formed in a silicon substrate, the silicon substrate including on a front surface side thereof an ejection orifice for ejecting liquid, a liquid flow path communicating to the ejection orifice, and an ejection energy generating element for generating energy for ejecting the liquid from the ejection orifice, the liquid supply port communicating to the liquid flow path to supply the liquid, the process comprising forming from a back surface of the silicon substrate the liquid supply port that passes through the silicon substrate by using the above-mentioned processing method of a silicon substrate.

Further features of the present invention will become apparent from the following description of exemplary embodiments with reference to the attached drawings.

### BRIEF DESCRIPTION OF THE DRAWINGS

FIG. 1 is a perspective view illustrating an exemplary liquid ejection head.

FIGS. 2A, 2B, 2C and 2D are schematic sectional views for illustrating process steps of a processing method of a silicon substrate, for forming a modified layer in the silicon substrate and forming an ink supply port passing through the substrate.

FIGS. 3A and 3B are schematic sectional views for illustrating a processing method of a silicon substrate in which modified layers are formed so as to be arranged in a direction perpendicular to a front surface of the silicon substrate.

FIGS. 4A and 4B are schematic sectional views for illustrating a processing method of a silicon substrate in which modified layers are formed so as to be arranged in a direction parallel to the front surface of the silicon substrate.

FIGS. 5A, 5B, 5C, 5D, 5E and 5F are schematic sectional views for illustrating a processing method of a silicon substrate in which the thickness of the modified layer is changed according to the silicon substrate thickness to form a depressed portion corresponding to a first supply port portion.

FIGS. 6A, 6B, 6C, 6D, 6E and 6F are schematic sectional views for illustrating a conventional substrate processing method in which a depressed portion corresponding to the first supply port portion is formed in silicon substrates having different thicknesses.

### DESCRIPTION OF THE EMBODIMENTS

According to the present invention, by forming in a substrate a modified layer with a high etching rate, dispersion in the substrate thickness can be absorbed. Therefore, for example, it is possible to suppress the influence of dispersion in the remaining amount of silicon among substrates after anisotropic etching using wet etching, and hence an opening can be formed by dry etching with good size precision, to thereby improve production efficiency.

In the following, an embodiment of the present invention is described with reference to the attached drawings.

In the production process of a structure formed so as to include a silicon substrate, in particular, a device such as an ink jet head, a processing method of a silicon substrate according to the present invention can be used to form a through-hole such as a liquid supply port of the ink jet head in the silicon substrate. The liquid supply port of the ink jet head may include a first supply port portion and a second supply port portion which communicate to each other. It is to be noted that the first supply port portion is a depression having a bottom surface in the substrate, and the second supply port portion is formed in the bottom surface of the first supply port portion.

When ink is used as the liquid, the liquid supply port, the first supply port portion, and the second supply port portion may be referred to as an ink supply port, a first ink supply port portion, and a second ink supply port portion, respectively. According to the present invention, prior to etching of the silicon substrate, a part of the silicon substrate in which the ink supply port is to be formed is irradiated with laser to form an amorphous modified layer in the silicon substrate.

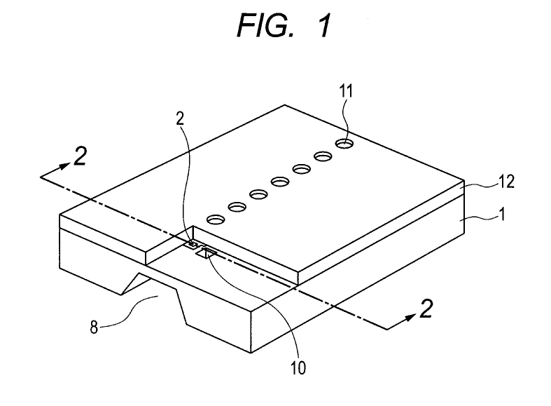

FIG. 1 is a perspective view illustrating an ink jet head as an example of a liquid ejection head produced using a substrate processing method according to the present invention. An electrothermal converting element (TaN) 2 which is a heater as an ejection energy generating element for ejecting ink is placed on a front surface of a silicon substrate 1 having a crystal axis (100). It is to be noted that the front surface of the silicon substrate as used herein means the front surface of two opposed surfaces (front surface and back surface) of the silicon substrate.

Further, a passivation layer (not shown) which is resistant to etching is formed on the front surface of the silicon substrate 1 as a protective film of the electrothermal converting element 2. It is to be noted that a control signal input electrode for driving the electrothermal converting element 2 is electrically connected to the element. Further, the thickness of the silicon substrate 1 may vary among sliced wafers, but the silicon substrate 1 may be formed with a thickness of, for example, 725±25 μm.

It is to be noted that a depressed portion 8 as a first ink supply port portion is formed in the silicon substrate 1. A through-hole 10 as a second ink supply port portion which passes through the silicon substrate 1 is formed in the depressed portion 8, that is, in a bottom surface of the depressed portion 8, to thereby form a passing-through opening (ink supply port) that passes through the substrate. It is to be noted that a bottom surface of the first ink supply port portion may be in parallel with the front surface of the silicon substrate 1. The two opposed surfaces of the silicon substrate are typically formed so as to be in parallel with each other, and thus, the bottom surface of the first ink supply port portion may be in parallel with the two opposed surfaces of the silicon substrate.

Further, an ink flow path forming member 12 having an ejection orifice 11 formed therein is formed on the front surface of the silicon substrate 1. Further, the description herein may be made with regard to a single silicon substrate 1, but in reality, a plurality of sliced wafers are processed similarly to simultaneously form a plurality of substrates for an ink jet head.

It is to be noted that, in producing an ink jet head, it is preferred to carry out the step of forming the ink flow path forming member 12 on the front surface of the silicon substrate 1 prior to the step of forming the ink supply port. More specifically, on the front surface of the silicon substrate 1, the ink flow path forming member 12 is formed first, which has the ejection orifice 11 for ejecting ink as liquid and an ink flow path as a liquid flow path communicating to the ejection orifice 11. After that, the step of forming the depressed portion 8 corresponding to the first ink supply port portion and the through-hole 10 corresponding to the second ink supply port portion is carried out, to thereby produce the liquid ejection head by using the substrate processing method according to the present invention.

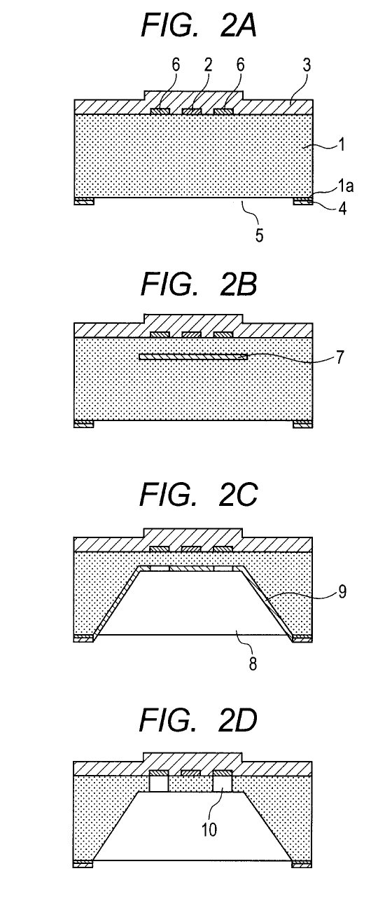

FIGS. 2A to 2D are schematic sectional views taken along the line 2-2 of FIG. 1 for illustrating a method of forming a modified layer in the silicon substrate and forming the ink supply port passing through the silicon substrate. The processing method of a silicon substrate including the process steps described below according to the present invention is described with reference to the attached drawings.

Etching Mask Layer Forming Step

First, as illustrated in FIG. 2A, an etching mask layer 4 having an opening portion 5 is formed on a back surface of the silicon substrate 1 having the front surface on which the electrothermal converting element 2, an etching stop layer 6, and a passivation layer 3 are formed. A SiO₂ layer la of the silicon substrate 1 can be removed using buffered hydrofluoric acid or the like. It is to be noted that the etching stop layer 6 may be formed using an Al—Si alloy, Al—Cu or Cu which are used as a material of a conductive film, or the like. It is to be noted that the electrothermal converting element 2 may be formed using Ta, SiN, or the like. The passivation layer 3 may be formed using SiO₂, SiN, or the like. The etching mask layer 4 may be formed using a polyamide, a polyimide, or the like.

Silicon Substrate Thickness Measuring Step

The thickness of the silicon substrate 1 is measured. The measuring method may be, for example, measurement using near-infrared radiation or measurement using a laser displacement gauge. It is preferred that the thickness of the silicon substrate 1 be 200 μm or larger and 800 μm or smaller.

Modified Layer Forming Step

As illustrated in FIG. 2B, the opening portion 5 in the etching mask layer 4 is irradiated with laser from the back surface of the silicon substrate 1 to form in the silicon substrate 1 the modified layer with the thickness varied according to the measured thickness of the substrate. It is to be noted that the modified layer as used herein means an amorphous processed modified layer.

A method of varying the thickness of the modified layer according to the measured thickness of the substrate is as follows. First, laser with a wavelength which passes through the substrate is collected in the material (in the silicon substrate) to selectively form a locally-processed modified layer in the vicinity thereof. The location of the focused point of the laser is vertically moved to determine the location at which the modified layer is processed. The pulse energy of the laser is controlled to form a modified layer having a desired thickness. The thickness of the thus formed modified layer may be measured using near-infrared radiation or using a laser displacement gauge.

The modified layer formed in the substrate may be only one layer or a plurality of layers. When a plurality of modified layers are formed in the silicon substrate, those layers may be placed so as to be arranged in a direction parallel to or perpendicular to the front surface of the silicon substrate. According to the present invention, the region of the modified layer may be changed according to the substrate thickness. In other words, as illustrated in FIG. 2B, a modified layer 7 may be formed along the whole long side of the silicon substrate so as to be in parallel to the front surface (back surface) of the silicon substrate 1.

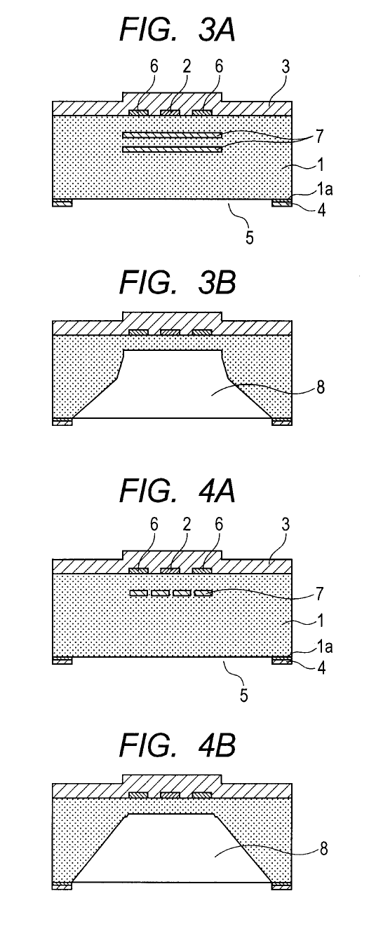

Further, as illustrated in FIG. 3A, a plurality of the modified layers 7 may be formed so as to be arranged in a direction perpendicular to the front surface of the substrate according to the thickness of the silicon substrate 1. It is to be noted that, in this case, the sum of the thicknesses of the plurality of modified layers may be varied according to the thickness of the silicon substrate.

Further, as illustrated in FIG. 4A, a plurality of the modified layers 7 may be formed so as to be arranged in a direction parallel to the front surface of the substrate according to the thickness of the silicon substrate 1.

Further, the laser for forming the modified layer 7 may be selected as necessary, and, for example, a femtosecond laser or a YAG laser (fundamental wave: wavelength of 1,060 nm) may be used. As described above, it is preferred to use such laser that may utilize multiphoton absorption with regard to silicon which is a material forming the silicon substrate. It is to be noted that the power and the frequency of the laser may be set as necessary.

It is to be noted that the thickness of the modified layer 7 is varied according to the thickness of the substrate 1. The thickness of the modified layer 7 may be set to a predetermined thickness by changing the focused point of the laser in the thickness direction. However, it is preferred that the modified layer 7 be formed so as to have a thickness of 2 μm or larger and 200 μm or smaller in the thickness direction according to the thickness of the silicon substrate 1. When the thickness of the modified layer 7 formed is 200 μm or smaller, it is possible to easily prevent the lengthening of time necessary for forming the modified layer 7.

According to the present invention, when the depressed portion as the first supply port portion is formed in each of silicon substrates having different thicknesses and the through-hole as the second supply port portion is formed in the bottom surface of each of the depressed portions, each of the depressed portions can be formed having that depth from the back surface of the substrate which is set so that dispersion does not occur in the dry etching time for forming the second supply port portion, in other words, so that dispersion does not occur in the distance from the front surface of the substrate to the depressed portion. Further, the modified layer may be formed for which the thickness, the location, and the like are set so that dispersion does not occur in the anisotropic etching time for forming the respective depressed portions.

According to the present invention, the modified layer may be formed in a region which corresponds to the depressed portion. Further, the modified layer may be formed in a region within the depressed portion and in the direction parallel to the front surface of the silicon substrate. Further, in the depressed portion forming step, the depressed portion may be formed by wet etching so as to reach the modified layer. In this case, all the modified layers formed in the substrate may be removed by etching, and the location of a modified layer which is the nearest to the front surface of the substrate may be set to be the location of the bottom surface of the depressed portion. Further, by forming the modified layer which is the nearest to the front surface of the substrate so as to be in parallel to the front surface, the bottom surface of the depressed portion may be formed so as to be in parallel to the front surface.

Depressed Portion Forming Step

As illustrated in FIG. 2C, anisotropic etching is carried out with regard to the silicon substrate 1 having the modified layer 7 formed therein to form a depressed portion 8 as the first supply port portion. As the etching method for forming the depressed portion 8, for example, crystal anisotropic etching may be carried out by immersing the silicon substrate 1 in a strongly alkaline solution of TMAH (tetramethylammonium hydroxide), KOH, or the like.

Through-Hole Forming Step

As illustrated in FIG. 2D, dry etching is carried out with regard to the silicon substrate 1 having the depressed portion 8 formed therein to form a through-hole 10 as the second supply port portions passing through to the front surface of the silicon substrate. An example of the dry etching method includes the Bosch process. It is to be noted that, as a mask 9 which has an opening and which is used for the dry etching as illustrated in FIG. 2D, a material such as a protective resist or a dry film may be used.

### EXAMPLES

### Example 1

A substrate for an ink jet head was formed according to FIGS. 2A to 2D. It is to be noted that, as described above, in reality, a plurality of sliced wafers are processed similarly to produce a plurality of substrates for an ink jet head. However, in this case, description is made in the following focusing on each silicon substrate 1 of three wafers having different thicknesses.

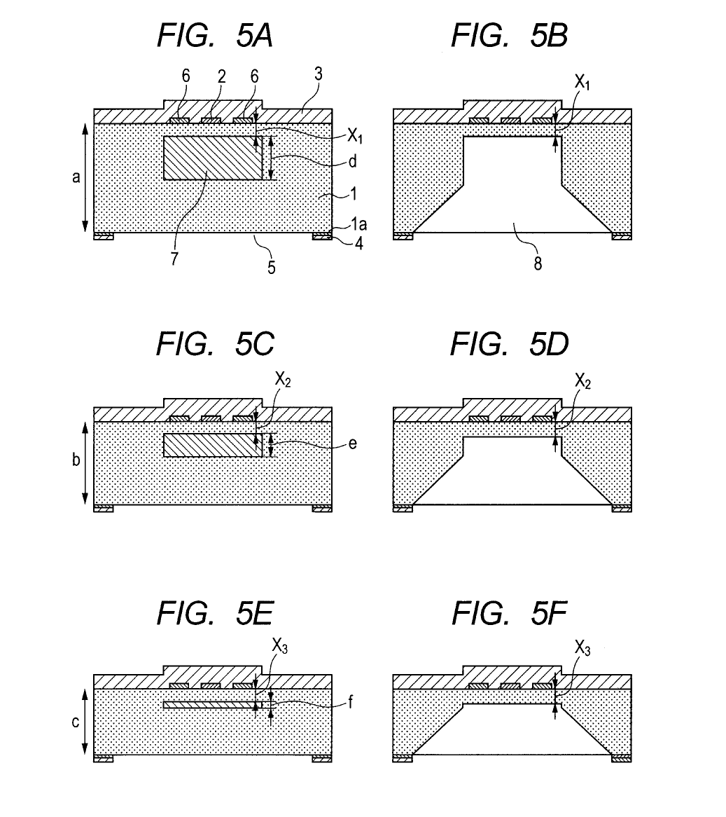

FIGS. 5A and 5B illustrate the substrate 1 having a thickness ‘a’ of 750 μm. FIGS. 5C and 5D illustrate the substrate 1 having a thickness ‘b’ of 725 μm. FIGS. 5E and 5F illustrate the substrate 1 having a thickness ‘c’ of 700 μm. It is to be noted that, although not shown in the figures, the thicknesses of the respective substrates are values measured using near-infrared radiation before the modified layer 7 described below was formed. The following operation was carried out with regard to the respective substrates 1.

First, as illustrated in FIG. 2A, the etching stop layer 6 formed of an Al—Si alloy was formed on the front surface of the silicon substrate 1 at each location corresponding to a portion for forming the through-hole as the second supply port portion. Further, the electrothermal converting element 2 was formed on the front surface of the silicon substrate 1, and, as the protective film thereof, the passivation layer 3 resistant to etching was formed.

On the other hand, on the back surface of the silicon substrate 1, a polyamide resin was laminated on the SiO₂ layer 1a of the silicon substrate 1 to form the etching mask layer 4 formed of the polyamide resin having the opening portion 5. The SiO₂ layer la in the opening portion 5 was removed by etching using buffered hydrofluoric acid or the like to expose the silicon surface.

As illustrated in FIG. 2B, the opening portion 5 in the etching mask layer 4 was irradiated with laser which is a fundamental wave (wavelength of 1,060 nm) of a YAG laser from the back surface side to the front surface side of the (100) surface of the silicon substrate 1, to thereby form the amorphous modified layer 7 in the silicon substrate 1. It is to be noted that the power and the frequency of the laser were set to appropriate values.

In this case, the laser was collected at the focal point at a depth of 125 μm from the front surface of the silicon substrate 1 to form the modified layer 7 by laser processing utilizing multiphoton absorption along the long side direction of the silicon substrate (substrate for ink jet head) 1. The etching of the modified layer 7 was carried out at relatively high rate because the modified layer 7 was in an amorphous state. It is to be noted that, in Example 1, the thickness of the modified layer 7 was in a range of 75 to 125 μm. More specifically, thicknesses d, e, and f of the modified layers 7 in the respective substrates illustrated in FIGS. 5A, 5C, and 5E were set to 125 μm, 100 μm, and 75 μm, respectively. Further, distances X₁, X₂, and X₃ from the front surface of the silicon substrate to the modified layers (distances from the front surface of the substrate to the depressed portion 8 to be described below) were all set to 125 μm.

Next, as illustrated in FIG. 2C, the depressed portion 8, which was not a through-hole yet, was formed. More specifically, first, etching was carried out at 80° C. for 16 hours using a 22%-by-mass TMAH solution with a mask of the etching mask layer 4 formed on the back surface of the silicon substrate 1 and formed of a polyamide resin. In the etching, the (111) surface with low etching rate was formed somewhere, while the etching progressed along the (001) surface and the (011) surface with high etching rate somewhere else. Finally, the (111) surface with low etching rate was formed. Thus, the modified layer 7 formed in the silicon substrate 1 for which the etching rate was relatively high was removed by etching to form the depressed portion 8 having a bottom surface that was in parallel to the front surface. It is to be noted that the etching was completed at a depth of 125 μm from the front surface of the substrate. After that, as the mask 9, a protective resist for dry etching having an opening which corresponded to the second ink supply port portion was formed in the depressed portion 8, that is, on the whole inner surfaces (bottom and side walls) of the depressed portion 8.

Then, as illustrated in FIG. 2D, dry etching was carried out using the protective resist as the mask until the through-hole 10 passing through to the front surface of the silicon substrate 1 was formed. As the dry etching, the Bosch process was used. As the etching gas, C₄F₈ and SF₆ were caused to flow alternately. The etching time was 13 minutes. The dry etching was completed when reaching the etching stop layer 6. After the etching, the mask 9 was removed by wet etching.

Further, although not shown, the etching stop layer 6 formed around the opening portion of the through-hole 10 in the front surface of the silicon substrate 1 was removed by wet etching, and a part of the passivation layer 3 was removed by dry etching. Further, the etching mask layer 4 having the opening portion 5 for forming the depressed portion 8 in the back surface of the silicon substrate 1 was removed by dry etching. In this way, the substrate for an ink jet head including the first supply port portion (depressed portion 8) and the second supply port portion (through-hole 10) passing through the silicon substrate 1 from the back surface to the front surface was obtained.

In a conventional substrate processing method, when substrates having thicknesses different from each other by, for example, 50 μm are simultaneously etched by crystal anisotropic etching for the same etching time, the remaining amount of the silicon after the etching differs, more specifically, the distance from the front surface of the silicon substrate to the depressed portion 8 differs by 50 μm between the substrates. Therefore, in the conventional method, as in a comparative example described below, the dry etching time is changed between the substrates in forming a passing-through opening. However, according to the present invention, by forming the modified layer in the substrate, the influence of the difference in the substrate thickness may be eliminated, and hence, even when substrates having thicknesses different from each other by 50 μm were used as illustrated in FIGS. 5A and 5E, the dry etching time for both the substrates was able to be the same 13 minutes. Accordingly, simultaneous etching of wafers could be performed in a plurality of chambers, and thus, the opening was able to be formed with good size precision, to thereby improve the production efficiency.

### Examples 2 and 3

Substrates for an ink jet head of Examples 2 and 3 were each formed similarly to the case of Example 1 except that a plurality of modified layers were formed and arranged as described below. It is to be noted that the thicknesses of the substrates 1 in Examples 2 and 3 were 750 μm and 720 μm, respectively. FIGS. 3A and 3B illustrate Example 2 while FIGS. 4A and 4B illustrate Example 3.

In Example 2, as illustrated in FIG. 3A, two modified layers 7 were formed and arranged in the direction perpendicular to the front surface of the substrate 1. It is to be noted that the thickness of each of the modified layers was 25 μm and the distance from the front surface of the substrate to the modified layers was 125 μm. In this case, also similarly to the case of Example 1, the etching was carried out such that the modified layers 7 with relatively high etching rate were removed in the order from the back surface side to obtain the shape illustrated in FIG. 3B.

In Example 3, as illustrated in FIG. 4A, a plurality of modified layers 7 were formed and arranged in the direction parallel to the front surface of the substrate 1. It is to be noted that the thickness of each of the modified layers was 20 μm and the distance from the front surface of the substrate to the modified layers was 125 μm. In this case, the etching was carried out such that the modified layers 7 with relatively high etching rate were similarly removed and the silicon between the modified layers is etched to obtain the shape illustrated in FIG. 4B.

Those examples have the process step of irradiating the opening in the etching mask layer 4 on the back surface of the substrate with laser to form one modified layer in the substrate 1 so as to be arranged in the direction parallel to the front surface of the silicon substrate 1, or to form a plurality of modified layers in the substrate 1 so as to be arranged in the direction parallel to or perpendicular to the front surface of the substrate. It is to be noted that the modified layers are layers extending in parallel to the front surface of the silicon substrate 1. By providing those modified layers, dispersion in the etching time due to dispersion in the thickness of the silicon substrate 1 may be suppressed. This may shorten the anisotropic etching time of the silicon substrate 1 as well as the dry etching time thereafter. Therefore, according to the present invention, the precision of the opening in the front surface of the ink supply port can be improved and the manufacturing costs of the ink jet head can be reduced.

### Comparative Examples

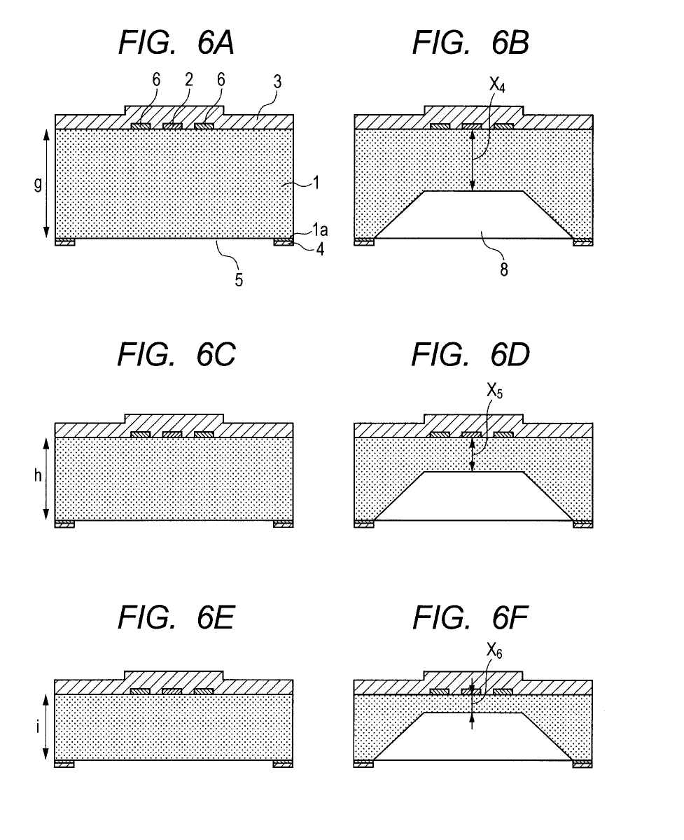

FIGS. 6A to 6F are schematic sectional views for illustrating a conventional substrate processing method. Substrates for an ink jet head were formed similarly to the case of Example 1 except that no modified layer was formed. It is to be noted that, similarly to the case of Example 1, a plurality of wafers were simultaneously processed similarly to produce a plurality of substrates for an ink jet head. Description is made in the following focusing on each silicon substrate 1 of three wafers having different thicknesses.

FIGS. 6A and 6B illustrate the substrate 1 having a thickness g of 750 μm. FIGS. 6C and 6D illustrate the substrate 1 having a thickness h of 725 μm, and FIGS. 6E and 6F illustrate the substrate 1 having a thickness i of 700 μm. With regard to the substrates illustrated in FIGS. 6A, 6C, and 6E, a 22%-by-mass TMAH solution was used to carry out etching at 80° C. for 20 hours to form the depressed portions 8 illustrated in FIGS. 6B, 6D, and 6F, respectively. The depths of the depressed portions 8 (distances from the back surface of the silicon substrate 1 to the bottoms of the depressed portions) were all 600 μm. Therefore, distances X₄, X₅, and X₆ from the front surface of the substrate 1 to the depressed portions 8 illustrated in FIGS. 6B, 6D, and 6F were 150 μm, 125 μm, and 100 μm, respectively.

Then, although not shown, dry etching was carried out similarly to the case of Example 1 to form the through-hole (second supply port portions) passing through the silicon substrate. However, in the comparative examples, the distance from the front surface of the substrate 1 to the depressed portion 8 varies, and thus it was necessary to change the etching time for forming the second supply port portion according to the thickness of the substrate. It is to be noted that the dry etching times of the substrates illustrated in FIGS. 6B, 6D, and 6F were 16 minutes, 13 minutes, and 11 minutes, respectively.

Further, similarly to the case of Example 1, the etching stop layer 6, a part of the passivation layer 3, the etching mask layer 4, and the mask 9 were removed to obtain the substrates for an ink jet head having the supply port (first supply port portion and second supply port portion) passing through the silicon substrate 1 from the back surface to the front surface.

According to the present invention, the processing method of a silicon substrate and the process for producing a liquid ejection head are provided, which are capable of suppressing the influence of dispersion in the substrate thickness so as to form an opening in the silicon substrate with good size precision, to thereby improve the production efficiency.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-226452, filed Oct. 6, 2010, which is hereby incorporated by reference herein in its entirety.

What is claimed is:

1. A processing method of a silicon substrate, comprising the steps of:
(a) forming on a back surface of a silicon substrate an etching mask layer having an opening portion;
(b) measuring a thickness of the silicon substrate;
(c) irradiating the opening portion in the etching mask layer with laser from the back surface of the silicon substrate to form in the silicon substrate a modified layer with a thickness that is varied according to the measured thickness of the silicon substrate;
(d) carrying out anisotropic etching with regard to the silicon substrate having the modified layer formed therein to form in the back surface a depressed portion which does not pass through the silicon substrate and which has a bottom surface in the silicon substrate; and
(e) carrying out dry etching in the depressed portion to form a through-hole passing from the bottom surface of the depressed portion to a front surface of the silicon substrate.

2. A processing method of a silicon substrate according to claim 1, wherein in step (c) the modified layer is formed by utilizing multiphoton absorption by the laser.

3. A processing method of a silicon substrate according to claim 1, wherein in step (c) a plurality of the modified layers are formed so as to be arranged in a direction perpendicular to the front surface of the silicon substrate.

4. A processing method of a silicon substrate according to claim 1, wherein in step (c) a plurality of the modified layers are formed so as to be arranged in a direction parallel to the front surface of the silicon substrate.

5. A processing method of a silicon substrate according to claim 1, wherein in step (c) the modified layer is formed in a region within the depressed portion so as to be in parallel to the front surface of the silicon substrate.

6. A processing method of a silicon substrate according to claim 1, wherein in step (d) the depressed portion that reaches the modified layer is formed by wet etching.

7. A processing method of a silicon substrate according to claim 1,
wherein the depressed portion has a bottom surface that is in parallel to the front surface of the silicon substrate, and
wherein in step (e) the through-hole passing through to the front surface of the silicon substrate is formed in a bottom surface of the depressed portion, the bottom surface being in parallel to the front surface of the silicon substrate, to thereby form a passing-through opening that passes through the silicon substrate.

8. A process for producing a liquid ejection head in which a liquid supply port is formed in a silicon substrate, the silicon substrate including on a front surface side thereof an ejection orifice for ejecting liquid, a liquid flow path communicating to the ejection orifice, and an ejection energy generating element for generating energy for ejecting the liquid from the ejection orifice, the liquid supply port communicating to the liquid flow path to supply the liquid, the process comprising forming from a back surface of the silicon substrate the liquid supply port that passes through the silicon substrate by using the processing method of a silicon substrate according to claim 1.
